(19) United States
(12) Patent Application Publication
(10) Pub. No.: US 2010/0019289 A1
(43) Pub. Date: Jan. 28, 2010

(54) Junction Field Effect Transistor Using Silicide Connection Regions and Method of Fabrication

(75) Inventors: Ashok K. Kapoor, Palo Alto, CA (US); Madhukar B Vora, Los Gatos, CA (US)

Correspondence Address: BAKER BOTTS L.L.P., 2001 ROSS AVENUE, SUITE 600, DALLAS, TX, 75201-2980, US

(73) Assignee: DSM Solutions, Inc., Los Gatos, CA (US)

(21) Appl. No.: 12/180,098

(22) Filed: Jul. 25, 2008

(51) Int. Cl. H01L 29/80; H01L 21/337

(52) U.S. Cl. 257/256; 438/186; 257/E29.31; 257/E21.445

(57) ABSTRACT

A junction field effect transistor comprises a semiconductor substrate and a well region formed in the substrate. A source region of a first conductivity type is formed in the well region. A drain region of the first conductivity type is formed in the well region and spaced apart from the source region. A channel region of the first conductivity type is located between the source region and the drain region and formed in the well region. A gate region of a second conductivity type is formed in the well region. The transistor further includes first, second, and third connection regions. The first connection region is in ohmic contact with the source region and formed of silicide. The second connection region is in ohmic contact with the drain region and formed of silicide. The third connection region in ohmic contact with the gate region.

### TECHNICAL FIELD OF THE INVENTION

The present disclosure relates generally to semiconductor devices and more particularly to a junction field effect transistor using silicide connection regions.

### BACKGROUND OF THE INVENTION

In current transistor technologies, the contact terminals are formed using a polysilicon material while the active regions are formed using silicon. The current that flows from one contact terminal, such as a source terminal, to another contact terminal, such as a drain terminal, faces a contact resistance at the interface between the polysilicon and silicon materials. The voltage drop that results from this contact resistance reduces the efficiency of the transistor.

### SUMMARY OF THE INVENTION

In accordance with the present invention, the disadvantages and problems associated with prior junction field effect transistors using polysilicon contact terminals have been substantially reduced or eliminated.

In accordance with one embodiment of the present invention, a junction field effect transistor comprises a semiconductor substrate and a well region formed in the substrate. A source region of a first conductivity type is formed in the well region. A drain region of the first conductivity type is formed in the well region and spaced apart from the source region. A channel region of the first conductivity type is located between the source region and the drain region and formed in the well region. A gate region of a second conductivity type is formed over the channel region. The transistor further includes first, second, and third connection regions. The first connection region is in ohmic contact with the source region and formed of silicide. The second connection region is in ohmic contact with the drain region and formed of silicide. The third connection region in ohmic contact with the gate region.

Another embodiment of the present invention is a method for fabricating a junction field effect transistor having a well region formed in a substrate, a first connection region in ohmic contact with a source region, a second connection region in ohmic contact with a drain region, a channel region, and a third connection region in ohmic contact with a gate region. The method comprising forming a mask that covers the third connection region but not the first and second connection regions. Next, a layer of oxide is removed from the first connection region and from the second connection region. The method continues by removing the mask that covers the third connection region, wherein the third connection region has a layer of oxide on it. The method continues by depositing a first layer of metal on the first connection region, the second connection region, and the layer of oxide of the third connection region. The metal is thermally reacted with polysilicon of the first and second connection regions to form silicide in the first and second connection regions. The layer of oxide is then removed from the third connection region. The method continues by depositing a second layer of metal on the first connection region, the second connection region, and the third connection region. The metal is thermally reacted with polysilicon of the first, second, and third connection regions to form silicide in the first, second, and third connection regions.

An alternative method for fabricating the junction field effect transistor comprises depositing a first layer of metal on the first connection region and the second connection region. The method continues by depositing a second layer of metal on the first layer of metal and on the third connection region. The method concludes by thermally reacting the first and second layers of metal with polysilicon of the first and second connection regions, and the second layer of metal with polysilicon of the third connection region to form silicide in the first, second, and third connection regions.

The following technical advantages may be achieved by some, none, or all of the embodiments of the present invention.

The contact resistance at an interface between silicide and silicon is lower than the contact resistance at the interface between polysilicon and silicon. In particular, the contact resistance at an interface between polysilicon and silicon is approximately 200 Ω·μm², whereas the contact resistance at an interface between silicide and silicon, is approximately 10 Ω·μm². Thus, for a given area of contact, the contact resistance at an interface between a first connection region and a source region, and between a second connection region and a drain region, is reduced when those first and second connection regions are formed using silicide rather than polysilicon. By reducing the contact resistance at these interfaces in this way, the operation of semiconductor device is improved.

### BRIEF DESCRIPTION OF THE DRAWINGS

For a more complete understanding of the present invention and its advantages, reference is now made to the following descriptions, taken in conjunction with the accompanying drawings, in which:

FIG. 1 illustrates one embodiment of a JFET using a silicide connection region;

FIGS. 2A-2G illustrate one method of fabricating the JFET of FIG. 1; and

FIGS. 3A-3E illustrate another method of fabricating the JFET of FIG. 1.

### DETAILED DESCRIPTION OF THE INVENTION

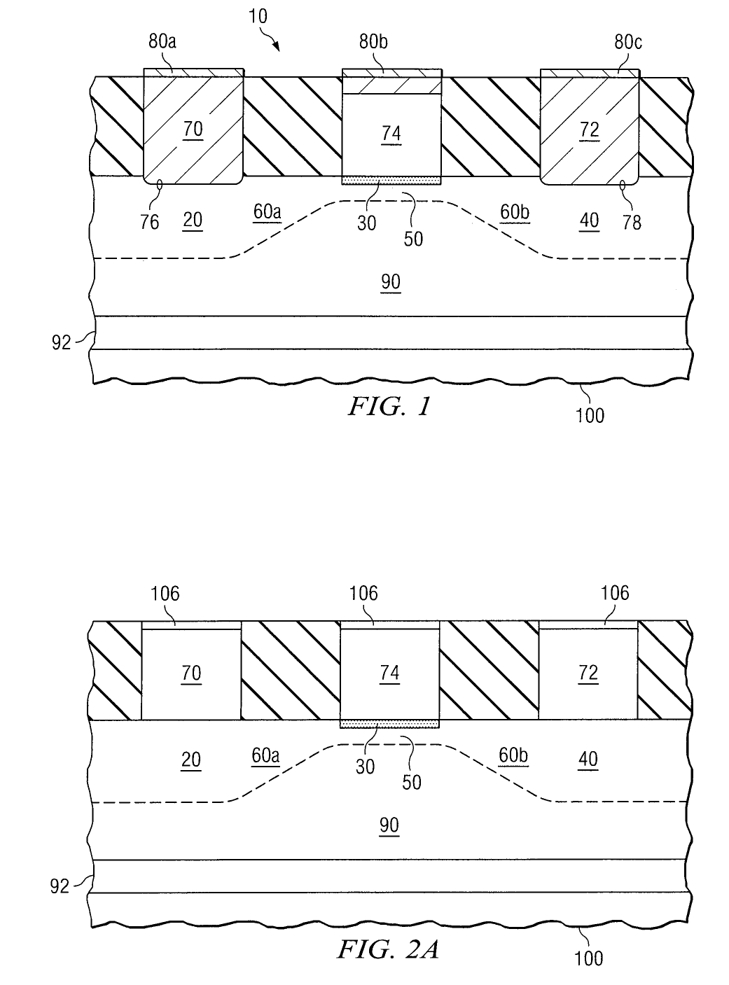

FIG. 1 illustrates a semiconductor device 10, according to certain embodiments. As shown in FIG. 1, device 10 may comprise a source region 20, a gate region 30, a drain region 40, a channel region 50, link regions 60a-b, silicide connection regions 70 and 72, polysilicon connection region 74, well region 90, and substrate 100. In some embodiments of device 10 using a Silicon-On-Insulator (SOI) architecture, device 10 further includes an insulating layer 92 between well region 90 and substrate 100. These regions are not necessarily drawn to scale. An interface 76 exists between silicide connection region 70 and source region 20. An interface 78 exists between silicide connection region 72 and drain region 40. In some embodiments, semiconductor device 10 is a junction field effect transistor (JFET). When appropriate voltages are applied to connection regions 70, 72, and 74 of semiconductor device 10, a current flows through channel region 50 between source region 20 and drain region 40, and through connection regions 70 and 72 at interfaces 76 and 78, respectively. The contact resistance at an interface between silicide and silicon is lower than the contact resistance at the interface between polysilicon and silicon. Thus, the formation of connection regions 70 and 72 using silicide, rather than polysilicon, reduces the contact resistance of interfaces 76 and 78. As a result, the performance of device 10 is improved.

Substrate 100 represents bulk semiconductor material to which dopants can be added to form various well regions and conductivity regions (e.g., source region 20, gate region 30, drain region 40, and channel region 50). Substrate 100 may be formed of any suitable semiconductor material, such as materials from Group IV, or a compound semiconductor from Group III and Group V of the periodic table. In particular embodiments, substrate 100 is formed of single-crystal silicon. In other embodiments, substrate 100 is an alloy of silicon and at least one other material. For example, substrate 100 may be formed of silicon-germanium. In yet other embodiments, substrate 100 is formed of single-crystal germanium. Substrate 100 may have a particular conductivity type, such as p-type or n-type. In particular embodiments, semiconductor device 10 may represent a portion of a substrate 100 that is shared by a plurality of different semiconductor devices (not illustrated in FIG. 1).

In those embodiments of device 10 using a Silicon-On-Insulator (SOI) architecture, device 10 includes an insulating layer 92. Insulating layer 92 may comprise silicon dioxide, sapphire, or any other suitable insulating material. Insulating layer 92 may be formed to have any suitable depth using any suitable fabrication techniques commonly known to those of skill in the art. Insulating layer 92 generally isolates the active regions of device 10 from substrate 100. This lowers the parasitic capacitance of device 10, which improves power consumption at matched performance. In addition, where an SOI architecture is used, the portion of connection regions 70 and 72 that extend into source region 20 and drain region 40, respectively, does not need to be strictly monitored. In particular, the silicide of connection regions 70 and 72 may extend deep into source region 20 and drain region 40, respectively, and even all the way to the insulating layer 92 of the SOI architecture, without adversely affecting the operation of device 10. This relaxed monitoring requirement may make fabrication of connection regions 70 and 72 easier.

Well region 90 may comprise p-type well regions or n-type well regions formed in substrate 100, as appropriate. A p-type well region 90 is appropriate when an n-type channel region 50 will be formed. An n-type well region 90 is appropriate when a p-type channel region 50 will be formed. For p-type well regions, boron, gallium, indium, and/or other p-type material atoms may be implanted. For n-type well regions, antimony, arsenic, phosphorous, and/or other n-type material atoms may be implanted.

Channel region 50 provides a path to conduct current between source region 20 and drain region 40. Channel region 50 is formed by the addition of dopants to well region 90. For example, the dopants may represent particles of n-type doping material such as antimony, arsenic, phosphorous, or any other appropriate n-type dopant. Alternatively, the dopants may represent particles of p-type doping material such as boron, gallium, indium, or any other suitable p-type dopant. Where the channel region 50 is doped with n-type impurities, a positive voltage is applied at drain region 40 with respect to source region 20 and electrons flow from source region 20 to drain region 40 to create a current when an appropriate voltage is applied to device 10. Where channel region 50 is doped with p-type impurities, holes flow from the source region 20 to the drain region 40 to create a current when an appropriate voltage is applied to device 10. In general, the polarity of the voltage applied at the source region 20 and drain region 40 is chosen to contain the carriers in the channel region 50, and not spill over in well region 90. The doping concentration for channel region 50 may range from 1E+17 atoms/cm³ to 1E+20 atoms/cm³. In general, the doping concentration of channel region 50 may be lower than source region 20 and drain region 40. Moreover, the doping concentration for channel region 50 may be maintained such that device 10 operates in an enhancement mode, with a current flowing between drain region 40 and source region 20 when a positive voltage differential is applied between source region 20 and gate region 30.

Source region 20 and drain region 40 each comprise regions formed by the addition of dopants to well region 90. Thus, for an n-channel device 10, source region 20 and drain region 40 are doped with n-type impurities. For a p-channel device 10, source region 20 and drain region 40 are doped with p-type impurities. In particular embodiments, source region 20 and drain region 40 have a doping concentration at or higher than 1E+18 atoms/cm³. In particular embodiments, source region 20 and drain region 40 are formed by the diffusion of dopants through corresponding connection regions 70a and 70c, respectively. For example, dopants are implanted in the polysilicon of regions 70a and 70c, and then the device is heated to diffuse the dopants into silicon to create the source and drain regions 20 and 40. Consequently, in such embodiments, the boundaries and/or dimensions of source region 20 and drain region 40 may be precisely controlled.

In some embodiments, device 10 may comprise link regions 60a and 60b. Link regions 60a and 60b may comprise active regions formed by doping well region 90 with n-type or p-type impurities, as appropriate. In particular embodiments, link regions 60a and 60b are doped using a different technique from that used to dope source region 20 and drain region 40. Because link regions 60a and 60b may be of the same conductivity type as source region 20 and drain region 40, however, the boundary between source region 20 and link region 60a and the boundary between drain region 40 and link region 60b may be undetectable once the relevant regions have been formed. For example, in particular embodiments, source region 20 and drain region 40 are formed by diffusing dopants through connection regions 70a and 70b, respectively. Ion implantation may then be used to add dopants to appropriate regions of well region 90, thereby forming link regions 60a and 60b. Because the doping concentrations for these regions may be similar or identical, the boundary between source region 20 and link region 60a and the boundary between drain region 40 and link region 60b may be substantially undetectable after semiconductor device 10 has been formed. Thus, channel region 50 may provide a path to conduct current between source region 20 and drain region 40 through link regions 60a and 60b.

Gate region 30 may be formed by doping well region 90 with a second type of dopant. As a result, gate region 30 has a second conductivity type. Thus, for an n-channel device 10, gate region 30 is doped with p-type impurities. For a p-channel device 10, gate region 30 is doped with n-type impurities. In particular embodiments, gate region 30 is doped with the second type of dopant to a concentration at or higher than 1E+18 atoms/cm³. As described further below, when a voltage is applied to gate region 30, the applied voltage alters the conductivity of the neighboring channel region 50, thereby facilitating or impeding the flow of current between source region 20 and drain region 40. As with regions 20 and 40, gate region 30 may be formed by diffusing dopants from a corresponding connection region 70c.

Connection regions 70, 72, and 74 comprise structures that provide an ohmic connection to source region 20, gate region 30, and drain region 40, respectively. In particular embodiments, connection regions 70-74 may be coplanar. Coplanar connection regions 70-74 may simplify the manufacturing and packaging of semiconductor device 10.

Connection regions 70 and 72 may be formed of any suitable silicide such as, for example, cobalt silicide, nickel silicide, titanium silicide, molybdenum silicide, etc. Connection region 74 may be formed of polycrystalline silicon, polycrystalline germanium, a silicon-germanium alloy, and/or any other suitable material. Connection region 74 may further have silicide cap as illustrated in FIG. 1. An interface 76 exists between silicide connection region 70 and source region 20. Furthermore, an interface 78 exists between silicide connection region 72 and drain region 40. The contact resistance at an interface between silicide and silicon is lower than the contact resistance at the interface between polysilicon and silicon. In particular, the contact resistance at an interface between polysilicon and silicon is approximately 200 Ω·μm², whereas the contact resistance at an interface between silicide and silicon, such as interface 76 or 78, is approximately 10 Ω·μm². Thus, for a given area of contact, the contact resistance between connection region 70 and source region 20, and between connection region 72 and drain region 40, is reduced when connection regions 70 and 72 are formed using silicide rather than polysilicon. By reducing the contact resistance at interfaces 76 and 78 in this way, the operation of device 10 is improved.

In operation, channel region 50 provides a voltage-controlled conductivity path between source region 20 and drain region 40 through link regions 60. More specifically, a voltage differential between gate region 30 and source region 20 (referred to herein as V_{GS}) controls channel region 50 by increasing or decreasing a width of a depletion region formed within channel region 50. The depletion region defines an area within channel region 50 in which holes and electrons have depleted semiconductor device 10. Because the depletion region lacks charge carriers, it will impede the flow of current between source region 20 and drain region 40 by forming an energy barrier. Moreover, as the depletion region expands or recedes, the portion of channel region 50 through which current can flow grows or shrinks, respectively. As a result, the conductivity of channel region 50 increases and decreases as V_{GS} changes, and semiconductor device 10 may operate as a voltage-controlled current regulator.

Semiconductor device 10 can comprise either a depletion mode device or an enhancement mode device. In depletion mode, when V_{GS}>0, the depletion region pinches off channel region 50 preventing current from flowing between source region 20 and drain region 40. When V_{GS}≦0, the depletion region recedes to a point that a current flows between source region 20 and drain region 40 through channel region 50. In enhancement mode, when V_{GS}≦0 the depletion region pinches off channel region 50 preventing current from flowing between source region 20 and drain region 40. When V_{GS}>0, the depletion region recedes to a point that a current flows between source region 20 and drain region 40 through channel region 50 when a positive voltage differential is applied between source region 20 and drain region 40 (referred to herein as V_{DS}).

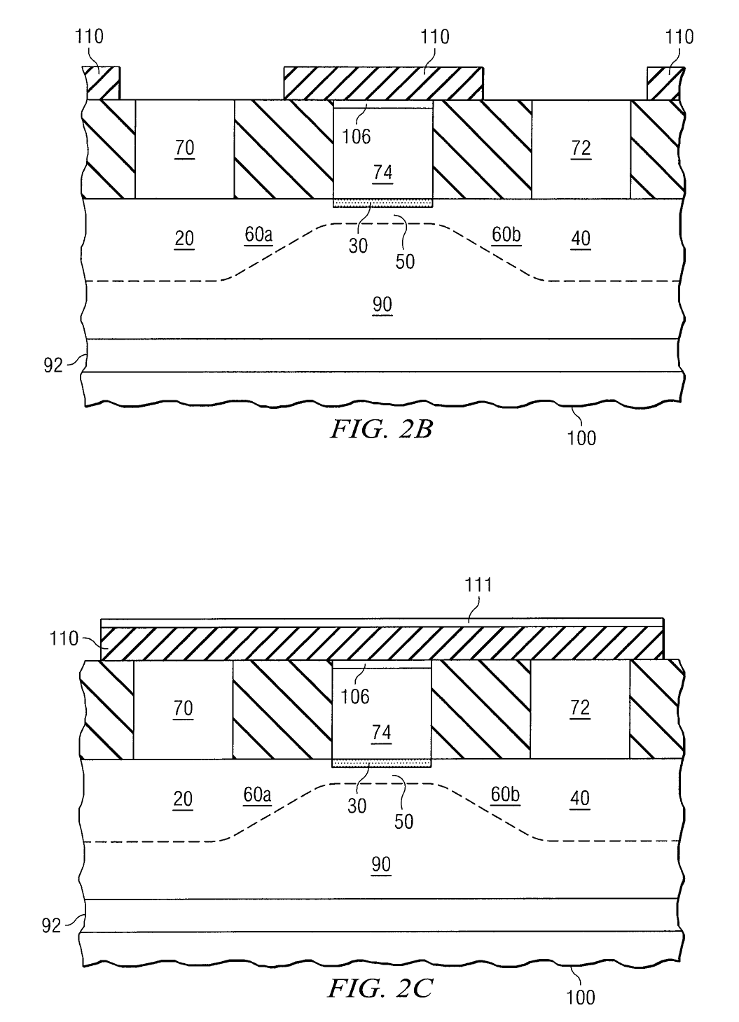

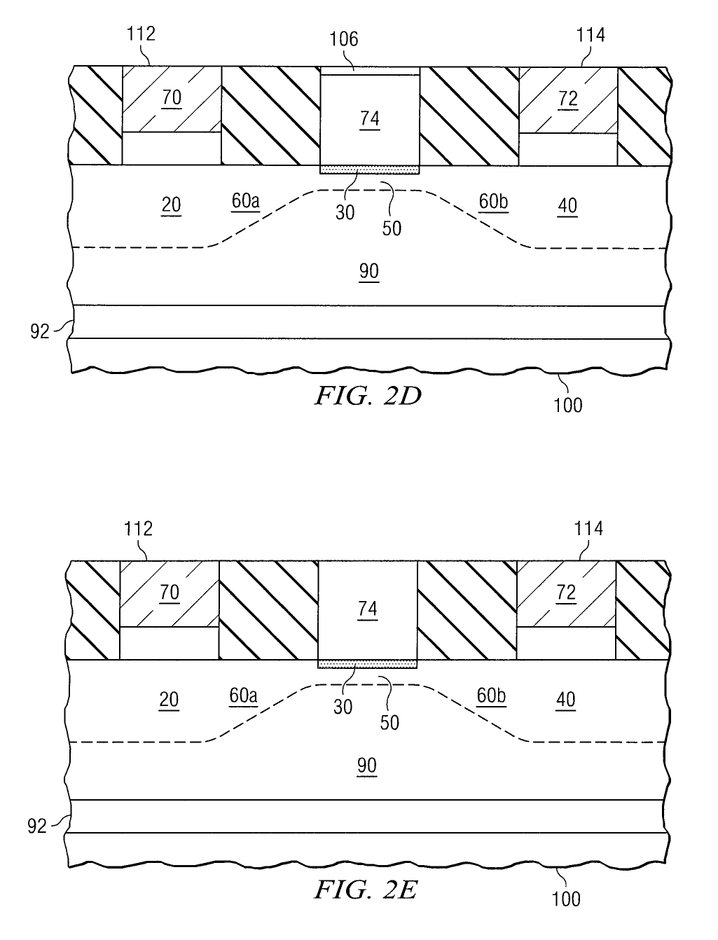

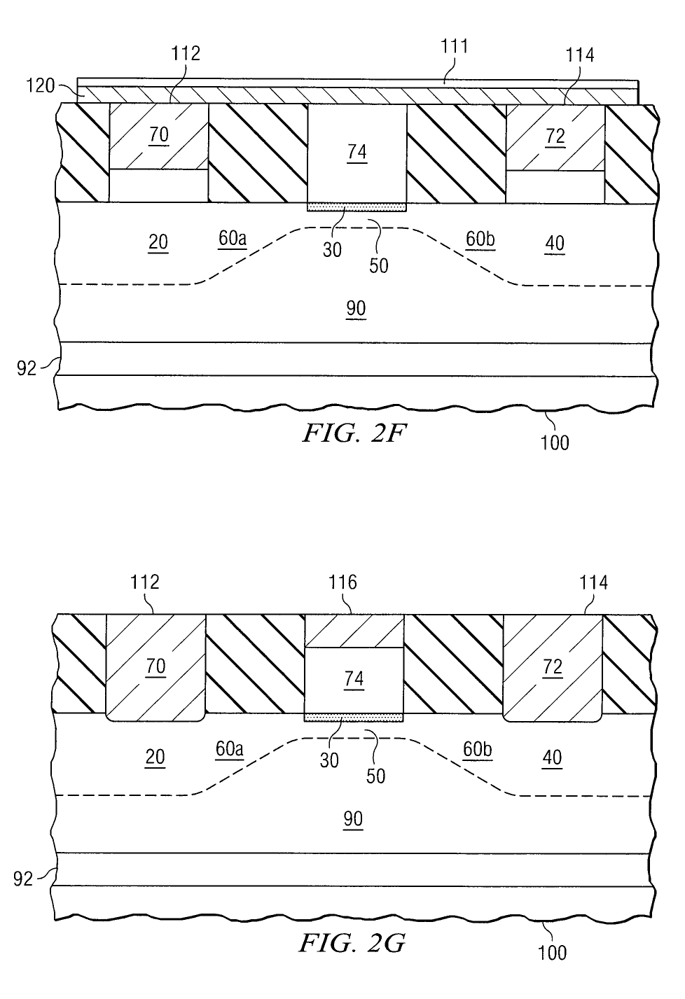

FIGS. 2A-2G illustrate one example method of fabricating device 10. The various elements of the semiconductor device depicted in FIG. 2 are not necessarily drawn to scale. The steps illustrated in FIGS. 2A-2G may be combined, modified, or deleted where appropriate. Additional steps may also be added to the example fabrication. Furthermore, the described steps may be performed in any suitable order.

FIG. 2A illustrates a cross-sectional view of device 10 after particular steps during fabrication have been completed to form the active regions of the transistor (e.g., source region 20, gate region 30, drain region 40, channel region 50, link regions 60a-b) in well region 90. In one embodiment, device 10 can be formed using an SOI architecture. In this embodiment, an insulating layer 92 is also formed between well region 90 and substrate 100. Moreover, as illustrated in FIG. 2A, particular steps during fabrication have already been completed to form connection regions 70, 72, and 74. However, at this point in the fabrication process, connection regions 70, 72, and 74 are formed using polysilicon. Moreover, each of connection regions 70, 72, and 74 has a thin layer of oxide 106 on it.

FIG. 2B shows the formation of a mask 108 that covers connection region 74 but not connection regions 70 and 72. Mask 108 may be formed using any suitable photolithography process such as, for example, by applying a layer of photoresist, selectively exposing the photoresist, and removing the unexposed photoresist. Next, the thin layer of oxide 106 is removed from the surface of connection regions 70 and 72. This removal may be performed using any suitable sputtering, etching, or other cleaning process. However, the layer of oxide 106 remains on connection region 74 because mask 110 protects it from the cleaning process.

FIG. 2C shows the removal of mask 108. At this point, the layer of oxide 106 has been removed from connection regions 70 and 72, but remains on connection region 74. Next, a first layer 110 of cobalt is applied across each of connection regions 70-74 using any suitable deposition technique such as, for example, physical vapor deposition or chemical vapor deposition. The cobalt layer 110 has a thickness ranging from 1 to 15 nm. In one embodiment, a thin passivating layer 111, such as of titanium nitride, may be applied to cobalt layer 110 using any suitable deposition technique. Because the layer of oxide 106 has been removed from connection regions 70 and 72, the cobalt in layer 110 will have an opportunity to react with the polysilicon in connection regions 70 and 72. However, because the layer of oxide 106 remains on connection region 74, the cobalt in layer 110 will not react with the polysilicon in connection region 74. The reaction of cobalt in layer 110 with the polysilicon in connection regions 70 and 72 is induced by heating the entire device at a temperature ranging from 500-700° C. for a time ranging from 30 seconds to 10 minutes. The passivating layer 111 is then removed. The unreacted cobalt is also removed by selective etching from the silicon wafer. Finally, the device is heated to complete the reaction and form CoSiₓ. Upon reacting with the polysilicon, the cobalt in layer 110 forms a layer of CoSiₓ, (where x can range from 0.5 and 2, and the value of x depends at least in part upon the reaction conditions) in the connection regions 70 and 72. In the formation of CoSiₓ, the amount of cobalt that reacts with silicon approximately follows the ratio of 1:3.5. Thus, every 10 nm of cobalt consumes approximately 35 nm of silicon. As a result, the thickness of CoSiₓ formed in connection regions 70 and 72 based on cobalt layer 110 ranges from 35 to 50 nm.

FIG. 2D illustrates the formation of CoSiₓ in each of connection regions 70 and 72 according to the reaction described above with regard to FIG. 2C. In particular, a layer 112 of CoSiₓ is formed in connection region 70 and a layer 114 of CoSiₓ is formed in connection region 72. FIG. 2E shows the removal of the layer 106 of oxide from connection region 74 using any suitable cleaning process, such as using a plasma etching process.

FIG. 2F shows the application of a second layer 120 of cobalt across each of connection regions 70-74 using any suitable deposition process. The cobalt layer 120 has a thickness ranging from 5 to 10 nm. In one embodiment, a thin passivating layer 111, such as of titanium nitride, may be applied to cobalt layer 120 using any suitable deposition technique. Because the layer of oxide 106 has been removed from connection region 74, as described above with reference to FIG. 2E, the cobalt in layer 120 will have an opportunity to react with the polysilicon in each of the connection regions 70-74. The reaction of cobalt in layer 120 with the polysilicon in connection regions 70-74 is again induced by heating the entire device at a temperature ranging from 500-700° C. for a time ranging from 30 seconds to 10 minutes. The passivating layer 111 is then removed. The unreacted cobalt is also removed by selective etching from the silicon wafer. Finally, the device is heated to complete the reaction and form CoSiₓ. Upon reacting with the polysilicon, the cobalt in layer 120 increases the presence of CoSiₓ in connection regions 70 and 72, and forms a layer 116 of CoSiₓ in connection regions 74, as illustrated in FIG. 2G. The CoSiₓ that is formed in connection regions 70-74 is also referred to as cobalt silicide, or simply silicide. Although the silicide is described above to be formed using cobalt, it should be understood that the silicide in connection regions 70-74 may be formed by thermally reacting any suitable metal (e.g., cobalt, nickel, titanium, molybdenum, etc.) with the pre-existing polysilicon of connection regions 70-74. The silicide in connection regions 70 and 72 extends into the active regions of the device to a depth of approximately 20 to 40 nm, depending on the thickness of layers 110 and 120. Thus, the silicide in connection region 70 extends into source region 20, and the silicide in connection region 72 extends into drain region 40. Next, additional steps are completed to form the remainder of device 10 using suitable fabrication techniques, including but not limited to annealing device 10.

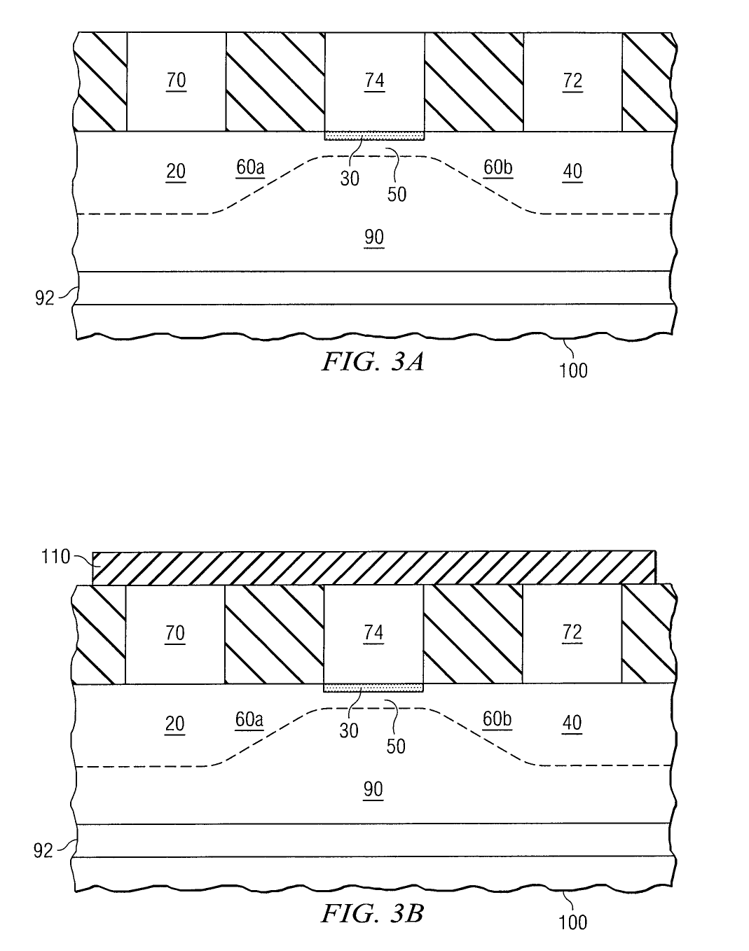

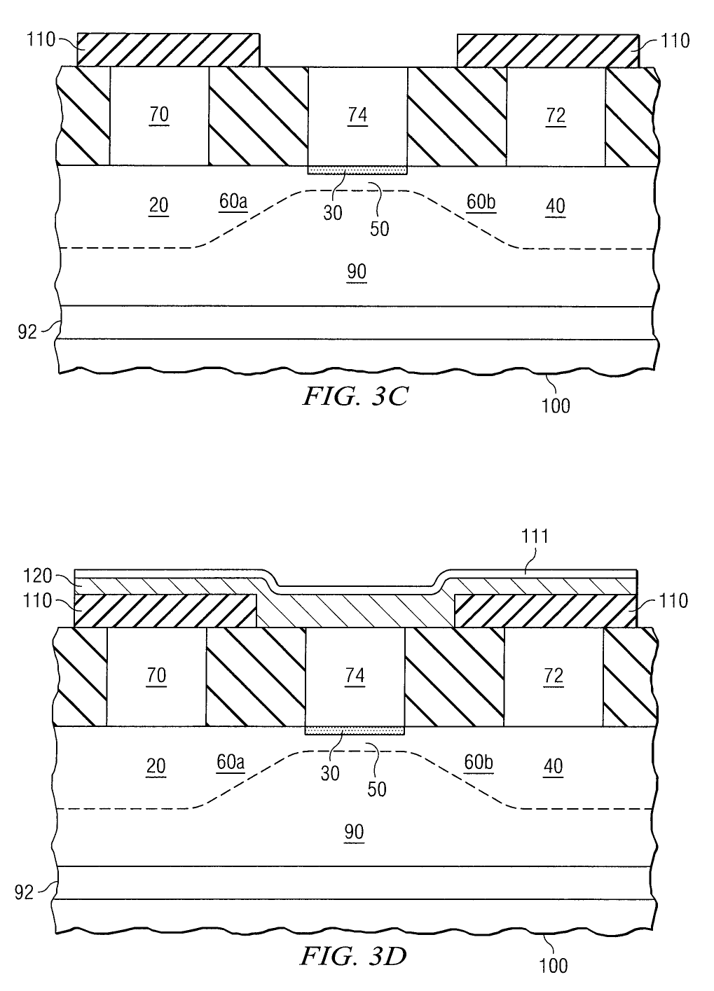

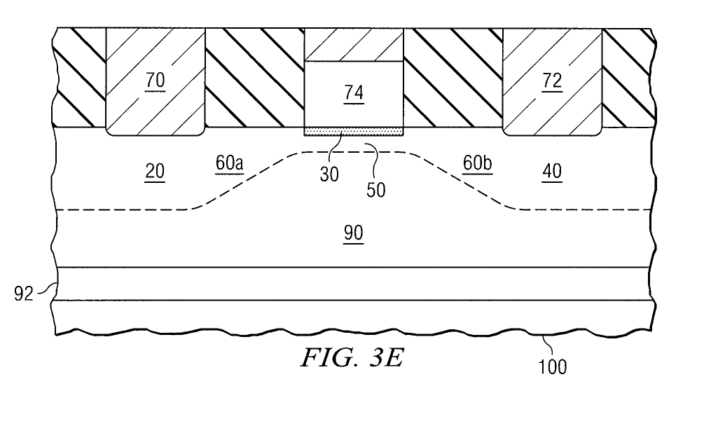

FIGS. 3A-3I illustrate another example method of fabricating device 10. The various elements of the semiconductor device depicted in FIG. 3 are not necessarily drawn to scale. FIG. 3A illustrates a cross-sectional view of device 10 after particular steps during fabrication have been completed to form the active regions of the transistor (e.g., source region 20, gate region 30, drain region 40, channel region 50, link regions 60a-b) in well region 90. In one embodiment, device 10 can be formed using an SOI architecture. In this embodiment, an insulating layer 92 is also formed between well region 90 and substrate 100. Moreover, as illustrated in FIG. 3A, particular steps during fabrication have already been completed to form connection regions 70, 72, and 74. However, at this point in the fabrication process, connection regions 70, 72, and 74 are formed using polysilicon. Notably, the layer of oxide 106 has already been removed from each of connection regions 70, 72, and 74.

FIG. 3B shows the application of a first layer 110 of cobalt across each of connection regions 70-74 using any suitable deposition process. The cobalt layer 110 has a thickness ranging from 1 to 15 nm. FIG. 3C shows the selective removal of a portion of cobalt layer 110 using any suitable masking and etching processes. As a result, the portion of cobalt layer 110 over connection region 74 is removed.

FIG. 3D shows the application of a second layer 120 of cobalt across each of connection regions 70-74 using any suitable deposition process. The cobalt layer 120 has a thickness ranging from 1 to 10 nm. In one embodiment, a thin passivating layer 111, such as of titanium nitride, may be applied to cobalt layer 120 using any suitable deposition technique. At this point, both cobalt layers 110 and 120 will have an opportunity to react with the polysilicon in each of the connection regions 70 and 72. However, only cobalt layer 120 will have an opportunity to react with the polysilicon in connection region 74. The reaction of cobalt in layers 110 and 120 with the polysilicon in connection regions 70-74 is induced by heating the entire device at a temperature ranging from 500-700° C. for a time ranging from 30 seconds to 10 minutes. The passivating layer 111 is then removed. The unreacted cobalt is also removed by selective etching from the silicon wafer. Finally, the device is heated to complete the reaction and form CoSiₓ. Upon reacting with the polysilicon, the cobalt in layers 110 and 120 forms silicide in connection regions 70 and 72 that extends into source region 20 and drain region 40, respectively, as illustrated in FIG. 3E. Moreover, the cobalt in layer 120 forms silicide in connection region 74 to a depth ranging from 15 to 35 nm. Next, additional steps are completed to form the remainder of device 10 using suitable fabrication techniques, including but not limited to annealing device 10.

Although the present invention has been described in detail, it should be understood that various changes, substitutions and alterations can be made hereto without departing from the scope of the invention as defined by the appended claims.

1. A junction field effect transistor, comprising:
a semiconductor substrate;
a well region formed in the substrate;
a source region of a first conductivity type which is formed in the well region;
a drain region of the first conductivity type which is formed in the well region and spaced apart from the source region;
a channel region of the first conductivity type which is located between the source region and the drain region and formed in the well region;
a gate region of a second conductivity type which is formed in the well region;
a first connection region in ohmic contact with the source region and formed of silicide;
a second connection region in ohmic contact with the drain region and formed of silicide; and
a third connection region in ohmic contact with the gate region.

2. The JFET of claim 1, wherein the silicide of the first and second connection regions comprises at least one of CoSiₓ, NiSₓ, WSiₓ, and MoSiₓ.

3. The JFET of claim 1, wherein the third connection region is formed of polysilicon.

4. The JFET of claim 1, wherein at least a portion of the first connection region extends into the source region.

5. The JFET of claim 1, wherein at least a portion of the second connection region extends into the drain region.

6. The JFET of claim 1, wherein the first connection region and the source region form an interface having a contact resistance that is less than the contact resistance of an interface between polysilicon and silicon.

7. The JFET of claim 1, further comprising an insulating layer between the well region and the substrate.

8. A method for fabricating a junction field effect transistor having a well region formed in a substrate, a first connection region in ohmic contact with a source region, a second connection region in ohmic contact with a drain region, a channel region, and a third connection region in ohmic contact with a gate region, the method comprising:
forming a mask that covers the third connection region but not the first and second connection regions;
removing a layer of oxide from the first connection region;
removing a layer of oxide from the second connection region;
removing the mask that covers the third connection region, wherein the third connection region has a layer of oxide on it;
depositing a first layer of metal on the first connection region, the second connection region, and the layer of oxide of the third connection region;
thermally reacting metal with polysilicon of the first and second connection regions to form silicide in the first and second connection regions;
removing the layer of oxide from the third connection region;
depositing a second layer of metal on the first connection region, the second connection region, and the third connection region; and
thermally reacting metal with polysilicon of the first, second, and third connection regions to form silicide in the first, second, and third connection regions.

9. The method of claim 8, wherein the layer of oxide on the third connection region prevents the metal from the first layer of metal from thermally reacting with polysilicon of the third connection region.

10. The method of claim 8, wherein at least one of the thermal reaction processes is performed at a temperature ranging from 500 to 700° C.

11. The method of claim 8, wherein at least one of the thermal reaction processes is performed for a time ranging from 30 seconds to 10 minutes.

12. The method of claim 8, further comprising depositing a passivating layer on the first layer of metal prior to the thermal reaction.

13. The method of claim 8, further comprising depositing a passivating layer on the second layer of metal prior to the thermal reaction.

14. The method of claim 8, wherein the metal in the first layer of metal and the second layer of metal comprises at least one of cobalt, nickel, titanium, and molybdenum.

15. The method of claim 8, wherein the first layer of metal comprises a thickness ranging from 1 to 15 nm.

16. The method of claim 8, wherein the second layer of metal comprises a thickness ranging from 1 to 10 nm.

17. The method of claim 8, wherein the silicide in the first connection region extends into the source region and the silicide in the second connection region extends into the drain region.

18. A method for fabricating a junction field effect transistor having a well region formed in a substrate, a first connection region in ohmic contact with a source region, a second connection region in ohmic contact with a drain region, a channel region, and a third connection region in ohmic contact with a gate region, the method comprising:
depositing a first layer of metal on the first connection region and the second connection region;
depositing a second layer of metal on the first layer of metal and on the third connection region; and
thermally reacting the first and second layers of metal with polysilicon of the first and second connection regions, and the second layer of metal with polysilicon of the third connection region to form silicide in the first, second, and third connection regions.

19. The method of claim 18, wherein depositing the first layer of metal comprises:
depositing the first layer of metal on the first connection region, the second connection region, and the third connection region; and
selectively removing the first layer of metal from the third connection region.

20. The method of claim 18, wherein the thermal reaction process is performed at a temperature ranging from 500 to 700° C.

21. The method of claim 18, wherein the thermal reaction process is performed for a time ranging from 30 seconds to 10 minutes.

22. The method of claim 18, further comprising depositing a passivating layer on the second layer of metal prior to the thermal reaction.

23. The method of claim 18, wherein the metal in the first layer of metal comprises at least one of cobalt, nickel, titanium, and molybdenum.

24. The method of claim 18, wherein the first layer of metal comprises a thickness ranging from 1 to 15 nm.

25. The method of claim 18, wherein the second layer of metal comprises a thickness ranging from 1 to 10 nm.

26. The method of claim 18, wherein the silicide in the first connection region extends into the source region and the silicide in the second connection region extends into the drain region.
